(19) United States
(12) Patent Application Publication
(10) Pub. No.: US 2024/0170429 A1
(43) Pub. Date: May 23, 2024

(54) SEMICONDUCTOR CHIP AND SEMICONDUCTOR PACKAGE INCLUDING THE SAME

(71) Applicant: SAMSUNG ELECTRONICS CO., LTD., Suwon-si (KR)

(72) Inventors: Sangho Cha, Suwon-si (KR); Yunrae Cho, Suwon-si (KR)

(21) Appl. No.: 18/346,371

(22) Filed: Jul. 3, 2023

(30) Foreign Application Priority Data
Nov. 17, 2022 (KR) 10-2022-0154699

(51) Int. Cl. H01L 23/00; H01L 23/498; H01L 25/065

(52) U.S. Cl. CPC H01L 24/09; H01L 23/49822; H01L 24/05; H01L 24/08; H01L 24/16; H01L 25/0657; H01L 2224/05647; H01L 2224/05655; H01L 2224/08052; H01L 2224/0903; H01L 2224/16148; H01L 2225/06513; H01L 2924/3511

(57) ABSTRACT

A semiconductor chip includes a semiconductor substrate that includes an upper surface and a lower surface opposite to the upper surface, a center pad disposed on a center portion of the upper surface and an edge portion disposes on an outer portion of the upper surface; a wiring structure that includes a wiring insulating layer disposed on a lower surface of the semiconductor substrate and a wiring pattern disposed in the wiring insulating layer and electrically connected to the semiconductor substrate; a first bump pad disposed on a first surface of the wiring structure and electrically connected to the wiring pattern; and a first connection bump that connects the first bump pad to an external device. The center pad has a regular octagon shape, and the edge pad has an extended octagon shape formed by extending squares from four non-continuous sides of a regular octagon.

### CROSS-REFERENCE TO RELATED APPLICATION

This application claims priority under 35 U.S.C. § 119 from Korean Patent Application No. 10-2022-0154699, filed on Nov. 17, 2022 in the Korean Intellectual Property Office, the contents of which are herein incorporated by reference in their entirety.

### TECHNICAL FIELD

Embodiments of the inventive concept are directed to a semiconductor chip and a semiconductor package that includes the semiconductor chip, and more particularly, to a semiconductor chip that has improved joint stability between a connection bump and a pad, and a semiconductor package that includes the semiconductor chip.

### DISCUSSION OF THE RELATED ART

As the size of various electric and electronic products becomes more miniaturized, many studies have been conducted to reduce size and increase capacity by mounting a larger number of chips on a limited size substrate. Accordingly, the size and thickness of a semiconductor package mounted on the substrate is gradually decreasing.

For example, a chip size package in which the size of a semiconductor chip is equal to or greater than 80% of the total size of a package has been proposed, and such a chip size package is being developed in various forms due to being light, thin and small.

Typical semiconductor packages and some chip size packages use a soldering method that uses a lead frame as a mounting method on a printed circuit board. However, a lead frame soldering method has an easy process progress and excellent reliability, but has a long electrical signal transmission length between a semiconductor chip and the printed circuit board.

Accordingly, to minimize an electrical signal transmission path between the semiconductor chip and the printed circuit board, a flip chip package structure that uses bumps has been proposed. The flip chip package has a structure in which the semiconductor chip is bonded to the printed circuit board by bumps formed on bonding pads of the semiconductor chip and electrical connection between the semiconductor chip and the printed circuit board is made simultaneously. Because electrical signal transmission between the semiconductor chip and the printed circuit board is performed only by bumps, the signal transmission path is very short, and thus, the flip chip package has improved electrical characteristics.

Therefore, joint stability of bumps that electrically connect a semiconductor chip and a printed circuit board in such a flip chip package need to be secured.

However, in a flip chip package, an edge portion of the semiconductor chip is relatively vulnerable to a non-wet phenomenon due to a warpage phenomenon caused by a difference in thermal expansion coefficient between the semiconductor chip and the printed circuit board.

Therefore, the non-wet risk between the pad and the connection bump and secure stable joint quality should be reduced.

### SUMMARY

Embodiments of the inventive concept reduce the occurrence of a non-wet risk in a bonding process of a semiconductor chip.

According to an embodiment of the inventive concept, there is provided a semiconductor chip.

A semiconductor chip includes a semiconductor substrate that includes an upper surface and a lower surface opposite to the upper surface, and a center pad disposed on the upper surface, a wiring structure that includes a wiring insulating layer disposed on a lower surface of the semiconductor substrate and a wiring pattern disposed in the wiring insulating layer and electrically connected to the semiconductor substrate, a first bump pad disposed on a first surface of the wiring structure and electrically connected to the wiring pattern, and a first connection bump that connects the first bump pad to an external device.

The semiconductor chip may further include an edge pad disposed on the upper surface of the semiconductor substrate, a second bump pad disposed on a first surface of the wiring structure and electrically connected to the wiring pattern, and a second connection bump that connects the second bump pad to an external device.

According to another embodiment of the inventive concept, there is provided a semiconductor package.

A semiconductor package includes a first semiconductor chip that includes a semiconductor substrate, a center pad disposed at a central portion of an upper surface of the semiconductor substrate, an edge pad disposed on an outer portion of the upper surface of the semiconductor substrate, a second semiconductor chip stacked on the first semiconductor chip, a first connection bump disposed between the first semiconductor chip and the second semiconductor chip and that contacts the center pad, and a second connection bump disposed between the first semiconductor chip and the second semiconductor chip and that contacts the edge pad. A shape of the edge pad differs from a shape of the center pad.

### BRIEF DESCRIPTION OF THE DRAWINGS

FIG. 1 is a cross-sectional view of a semiconductor chip according to an embodiment.

FIG. 2 is an enlarged cross-sectional view of an enlarged area indicated by AA in FIG. 1.

FIG. 3 is a plan view of the shape of a center pad.

FIGS. 4A and 4B are plan views of the shape of an edge pad.

FIG. 5 is a side view of a semiconductor chip according to an embodiment that shows positional relationships among points S₁, S₂, S₃, S₄, and C.

FIG. 6 is a side view of a semiconductor chip according to an embodiment that shows additional points S₂₂ and S₃₃.

FIG. 7 is a cross-sectional view of a semiconductor substrate according to an embodiment as viewed in a Z-axis direction.

FIG. 8 illustrates a case where the quality of a joint is poor because the contact between a connection bump and a pad is not perfect due to a warpage phenomenon of a semiconductor substrate.

FIG. 9 schematically illustrates a method of manufacturing a semiconductor package, according to a comparative example.

FIG. 10 illustrates a semiconductor package to which a semiconductor chip to that has dualized pad design is bonded, according to an embodiment.

### DETAILED DESCRIPTION

Hereinafter, embodiments of the inventive concept will be described in detail with reference to the accompanying drawings.

A first direction is a vertical direction in which a plurality of first and second conductive via patterns 221 and 225 extend, a second direction is a horizontal direction in which a plurality of first and second conductive line patterns 223 and 227 extend, and a third direction is a direction perpendicular to the first and second directions.

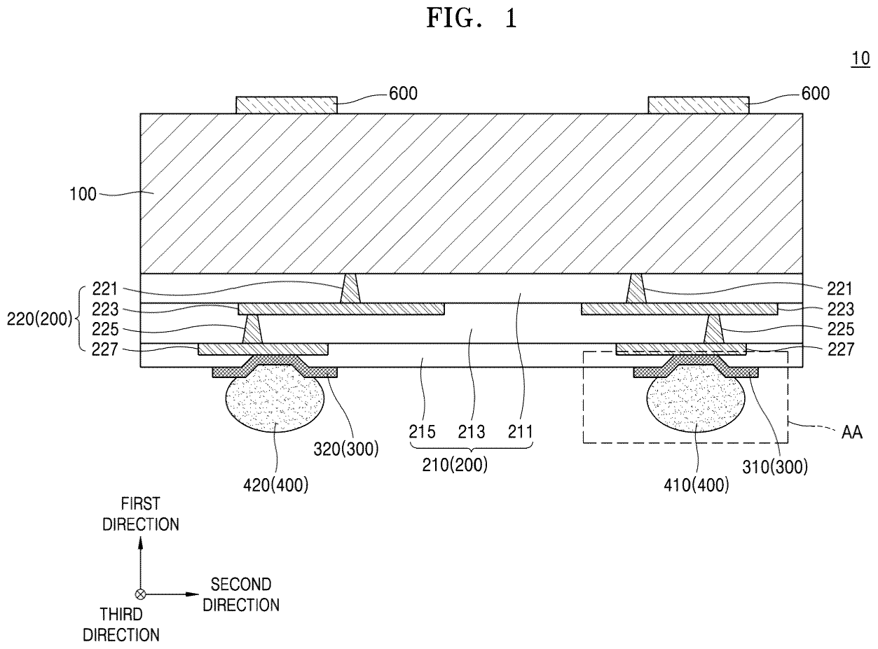

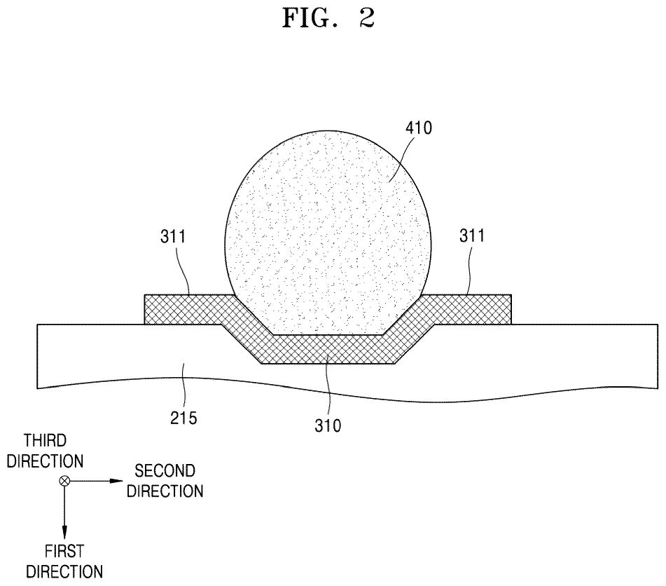

FIG. 1 is a cross-sectional view of a semiconductor chip 10 according to an embodiment, and FIG. 2 is an enlarged cross-sectional view of an area AA in FIG. 1.

Referring to FIG. 1, in an embodiment, the semiconductor chip 10 includes a semiconductor substrate 100, a wiring structure 200, a bump pad 300, and a connection bump 400. The area indicated by AA in FIG. 2 shows a third wiring insulating layer 215, the bump pad 300 and the connection bump 400.

The semiconductor chip 10 may be a memory chip or a logic chip. The memory chip may be, for example, a volatile memory chip, such as a one of a Dynamic Random Access Memory (DRAM) or a Static Random Access Memory (SRAM), or a non-volatile memory chip, such as one of a Phase-change Random Access Memory (PRAM), a Magnetoresistive Random Access Memory (MRAM), a Ferroelectric Random Access Memory (FeRAM) chip, or a Resistive Random Access Memory (RRAM). In some embodiments, the memory chip is a high bandwidth memory (HBM) DRAM semiconductor chip. In addition, the logic chip may be, for example, one of a microprocessor, an analog device, or a digital signal processor.

The semiconductor substrate 100 includes silicon, for example, one of a single crystal silicon, polycrystalline silicon, or amorphous silicon.

The wiring structure 200 includes a wiring insulating layer 210 and a wiring pattern 220. The wiring insulating layer 210 includes a plurality of insulating layers. Each of the insulating layers is formed from, for example, a material film that includes an organic compound. In some embodiments, each of the insulating layers is formed from a material film that includes an organic polymer material. In some embodiments, each of the insulating layers includes an insulating material made of a photo imageable dielectric (PID) material that can undergo a photolithography process. For example, each of the insulating layers includes a photosensitive polyimide (PSPI). Alternatively, in some embodiments, each of the insulating layers includes an oxide or a nitride. For example, each of the insulating layers includes silicon oxide or silicon nitride.

According to some embodiments, the wiring insulating layer 210 includes a first wiring insulating layer 211, a second wiring insulating layer 213, and a third wiring insulating layer 215 that are sequentially stacked. The first wiring insulating layer 211 is disposed on the lower surface of the semiconductor substrate 100. The second wiring insulating layer 213 is disposed on the lower surface of the first wiring insulating layer 211 and is spaced apart from the semiconductor substrate 100 in the first direction with the first wiring insulating layer 211 disposed therebetween. The third wiring insulating layer 215 is disposed on the lower surface of the second wiring insulating layer 213 and is spaced apart from the first wiring insulating layer 211 in the first direction with the second wiring insulating layer 213 disposed therebetween.

The wiring pattern 220 is disposed in the wiring insulating layer 210 and is electrically connected to the semiconductor substrate 100. The wiring pattern 220 includes conductive line patterns and conductive via patterns. The conductive line patterns include a plurality of first conductive line patterns 223 and a plurality of second conductive line patterns 227. The conductive via patterns include a plurality of first conductive via patterns 221 and a plurality of second conductive via patterns 225.

The conductive line patterns and the conductive via patterns include a metal, such as at least one of copper (Cu), aluminum (Al), tungsten (W), titanium (Ti), tantalum (Ta), indium (In), molybdenum (Mo), manganese (Mn), Cobalt (Co), tin (Sn), nickel (Ni), magnesium (Mg), rhenium (Re), beryllium (Be), gallium (Ga), or ruthenium (Ru), or an alloy thereof, but are not necessarily limited thereto.

The first wiring insulating layer 211 is positioned on the lower surface of the semiconductor substrate 100 and includes a first opening that exposes a part of the lower surface of the semiconductor substrate 100. The first wiring insulating layer 211 includes a plurality of first openings.

The first conductive via pattern 221 fills the first opening, extends in the first direction, and is connected to each of the first conductive line pattern 223 and the semiconductor substrate 100. The first conductive line pattern 223 are connected to the first conductive via pattern 221 on the lower surface of the first wiring insulating layer 211 and extend in a horizontal direction. According to some embodiments, the first conductive line pattern 223 and the first conductive via pattern 221 are formed together through a plating process and are integrated with each other.

The second wiring insulating layer 213 is disposed on the first wiring insulating layer 211 and the first conductive line pattern 223, and includes a second opening that exposes a part of the lower surface of the first conductive line pattern 223. The second wiring insulating layer 213 includes a plurality of second openings.

The second conductive via pattern 225 fills the second opening, extends in the first direction, and is connected to each of the first conductive line pattern 223 and the second conductive line pattern 227. The second conductive line pattern 227 is connected to the second conductive via pattern 225 on the lower surface of the second wiring insulating layer 213 and extends in the horizontal direction. According to some embodiments, the second conductive line pattern 227 and the second conductive via pattern 225 are formed together through a plating process and are integrated with each other.

The third wiring insulating layer 215 is disposed on the second wiring insulating layer 213 and the second conductive line pattern 227, and includes a third opening that exposes a part of the lower surface of the second conductive line pattern 227.

The wiring pattern 220 includes a seed layer. The seed layer is disposed between one of the insulating layers and one of the conductive line patterns, and is disposed between one of the insulating layers and one of the conductive via patterns. The seed layers is formed by physical vapor deposition, and the conductive line patterns and the conductive via patterns are formed by electroless plating. The seed layers include at least one of copper (Cu), titanium (Ti), titanium tungsten (TiW), titanium nitride (TiN), tantalum (Ta), tantalum nitride (TaN), chromium (Cr), aluminum (Al), or combinations thereof. In some embodiments, the seed layers may be Cu/Ti in which copper is deposited on titanium, or Cu/TiW in which copper is deposited on titanium tungsten. However, the seed layers are not necessarily limited to these materials.

The bump pad 300 is disposed on a lower surface of the third wiring insulating layer 215. A plurality of bump pads 300 are provided. According to some embodiments, the bump pads 300 have a protrusion that fills the third opening in the third wiring insulating layer 215 and protrudes from the side of the bump pad 300 in the first direction. The protrusion includes a groove that extends in the horizontal direction on the lower surface of the third wiring insulating layer 215 and has the connection bump 400 disposed at a center of the lower surface of the bump pad 300.

The bump pad 300 electrically connects the second conductive line pattern 227 to the connection bump 400. The bump pad 300 functions as an under bump metallurgy (UBM) on which the connection bump 400 is disposed. The bump pad 300 may have an arbitrary shape, but has a substantially circular shape when viewed from the first direction. In this specification, the fact that a shape is substantially circular means that a shape is designed to be a perfect circle, but the actually manufactured shape may deviate somewhat from a perfect circle due to process errors.

A plurality of bump pads 300 are provided and correspond to the number of connection bumps 400. According to some embodiments, when two connection bumps 400 are provided, a first bump pad 310 and a second bump pad 320 are provided.

The bump pad 300 may be a metal, such as copper (Cu) or nickel (Ni) or an alloy thereof, but is not necessarily limited thereto.

The connection bump 400 connects the bump pad 300 to an external device. The connection bump 400 and the semiconductor substrate 100 are electrically connected to each other by the wiring structure 200 and the bump pad 300. Accordingly, the semiconductor substrate 100 is electrically connected to and mounted on a module substrate or system board of an electronic product through the connection bump 400.

A plurality of connection bumps 400 are provided. According to some embodiments, the connection bump 400 includes a first connection bump 410 and a second connection bump 420.

The connection bumps 400 are made of, for example, a solder-ball. The connection bump 400 includes at least one of copper (Cu), silver (Ag), gold (Au), or tin (Sb). In some embodiments, the connection bump 400 has a height greater than that of the bump pad 300.

Referring to FIG. 2, in an embodiment, the first bump pad 310 has a protrusion that fills third openings in the third wiring insulating layer 215 and protrudes from the sides of the first bump pad 310 in the first direction. The protrusion extends in a horizontal direction on the lower surface of the third wiring insulating layer 215. For example, because the third wiring insulating layer 215 is disposed at the lowermost portion of the wiring structure 200, the lower surface of the third wiring insulating layer 215 is the lower surface of the wiring structure 200.

Referring back to FIG. 1, the semiconductor chip 10 includes pads 600 disposed on the upper surface of the semiconductor substrate 100. According to some embodiments, the pads 600 include nickel (Ni), but are not necessarily limited thereto. Each of the pads 600 is electrically connected to the wiring pattern 220 via a through an electrode that penetrates the semiconductor substrate 100.

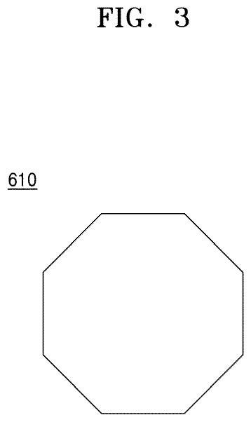

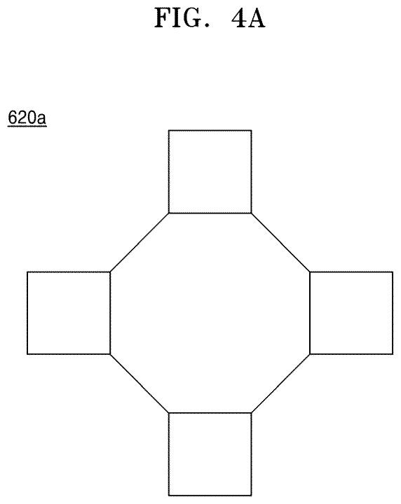

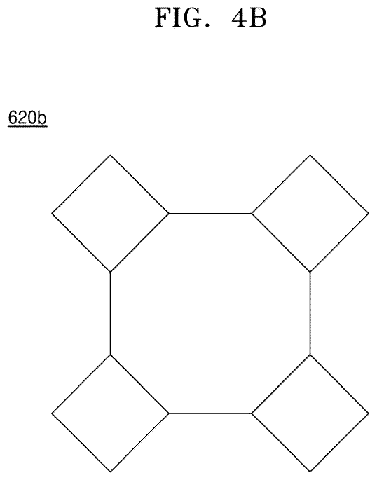

Referring to FIG. 1, FIG. 3, FIG. 4a and FIG. 4b, the pads 600 include a center pad 610 and an edge pad 620. For example, the center pad 610 is disposed in the center of the semiconductor chip 10, and the edge pad 620 is disposed in the outer portion of the semiconductor chip 10.

A thickness of the center pad 610 in the first direction ranges from 2 μm to 3 μm. A thickness of the edge pad 620 in the first direction is the same as that of the center pad 610, in the range of 2 μm to 3 μm.

FIG. 3 is a plan view of the shape of the center pad 610, and FIGS. 4A and 4B are plan views of the shapes of the edge pad 620.

Referring to FIG. 3, in an embodiment, the center pad 610 has a regular octagonal shape with a side length of 1 μm. Referring to FIGS. 4A and 4B, in some embodiments, the edge pad 620a and the edge pad 620b have an extended octagonal shape formed by extending and connecting squares that each have a side length of 1 μm from four non-continuous sides of eight sides of a regular octagon that has a side length of 1 μm.

According to some embodiments, a plurality of center pads 610 and a plurality of edge pads 620 are provided and are spaced apart in a horizontal direction.

By disposing the extended octagonal edge pad 620 on a partial area of the semiconductor substrate 100, a non-wet defect can be reduced despite a warpage phenomenon of the semiconductor chip 10. The warpage phenomenon occurs due to differences in thermal expansion coefficients between a chip and a substrate. When the semiconductor chip 10 is bonded to another chip or a substrate, due to the warpage phenomenon, a non-wet phenomenon can occur with high probability in which the connection bump 400 disposed at the edge of the semiconductor chip 10 does not contact the pad 600 disposed on another chip or substrate. When such a warpage phenomenon occurs, the connection bump 400 can crack. A void can occur in the connection bump 400, even in a plurality of high-temperature processes of stacking the plurality of semiconductor chips 10.

Therefore, according to embodiments of the inventive concept, the warpage phenomenon is reduced by disposing the edge pad 620 instead of the center pad 610 in a partial area of the semiconductor substrate 100. As described above, by dualizing the design of the pad 600, a non-wet risk can be reduced and a joint gap can be reduced.

In addition, by adding the edge pad 620, a contact area between the pad 600 and the connection bump 400 increases, and accordingly, a spreading phenomenon of the connection bump 400 is effectively induced.

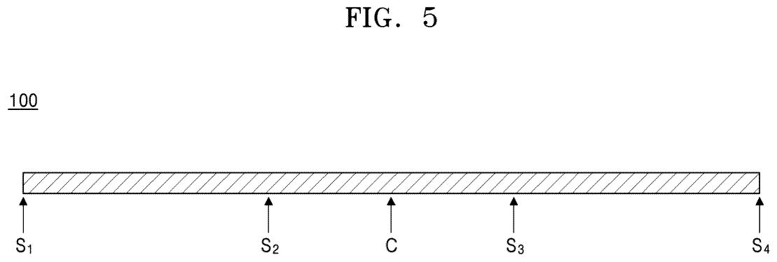

The center pad 610 is disposed at a central portion of the semiconductor chip 10, and the edge pad 620 is disposed at an edge portion of the semiconductor chip 10. The division of a center pad area 700 where the center pad 610 is disposed and an edge pad area 710 where the edge pad 620 is disposed is described below with reference to FIGS. 5, 6, and 7.

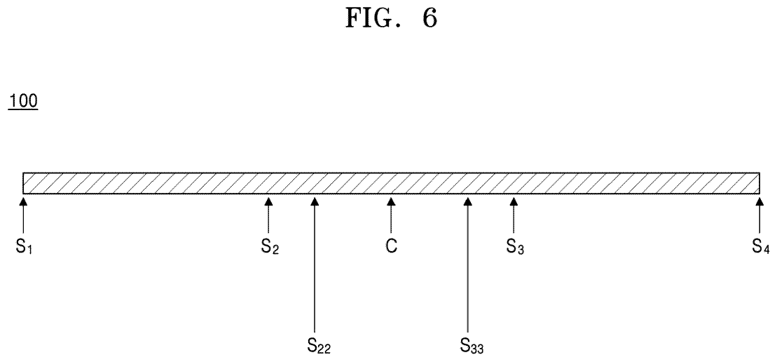

FIG. 5 is a schematic side view of the semiconductor chip 10 according to an embodiment that shows positional relationships among points S₁, S₂, S₃, S₄, and C. FIG. 6 is a schematic side view of the semiconductor chip 10 according to an embodiment that additionally shows points S₂₂ and S₃₃.

Referring to FIG. 5, in an embodiment, an end of one side surface of the semiconductor substrate 10 may be defined as the point S₁, an end of another side surface of the semiconductor substrate 10 may be defined as the point S₄. Dividing the distance between the point S₁ and the point S₄ into thirds, a point close to the point S₁ may be defined as the point S₂, a point distant from the point S₁ and close to point S₄ may be defined as the point S₃, and a central point between the end of one side surface and the end of the other side surface may be defined as the point C. For example, point S₂ is located at ⅓ of the distance from point S₁ to point S₄, and point S₃ is located at ⅔ of the distance from point S₁ to point S₄.

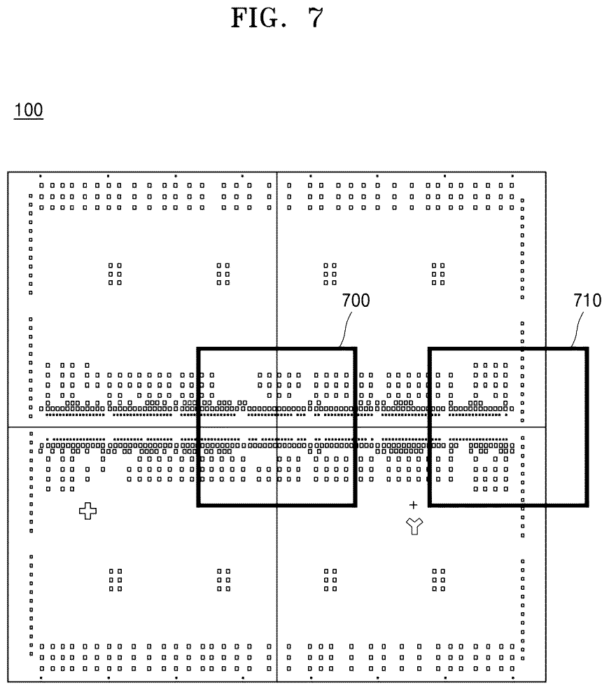

For example, a center pad area 700 (see FIG. 7) where the center pad 610 is disposed corresponds to an area between the points S₂ and S₃. An edge pad area 710 (see FIG. 7) where the edge pad 620 is disposed corresponds to an area between the points S₁ and S₂ and an area between the points S₃ and S₄.

The thickness between the upper and lower surfaces of the semiconductor chip 10 according to an embodiment is about 37 μm, but is not necessarily limited thereto, and a chip having a thickness less than 37 μm may be used. When the thickness of the semiconductor chip 10 decreases, the warpage phenomenon is more likely to occur, and thus, a width of the edge pad area 710 introduced to reduce the warpage phenomenon may be wider than in an embodiment described above.

This may be understood with reference to FIG. 6. When a chip that has a thickness less than 37 μm is used, the point S₂ may shift to a point S₂₂ between the points S₂ and C determined by dividing the distance from one side surface to the other side surface of the semiconductor substrate 10 into thirds, and the new point S₃ may shift to a point S₃₃ between the points S₃ and C determined by dividing the distance from one side surface to the other side surface of the semiconductor substrate 10 into thirds. For example, the points S₂₂ and S₃₃ are spaced apart from the point C by the same distance.

As described above, by replacing the points S₂ and S₃ with the points S₂₂ and S₃₃ and expanding the edge pad area 710, the technical concept of embodiments of the inventive concept can be applied even when a chip that has a greater warpage phenomenon is used.

FIG. 7 is a plan view of the semiconductor chip 10 according to an embodiment. The central portion of the semiconductor substrate 100 corresponds to the center pad area 700. An edge portion of the semiconductor substrate 100 corresponds to the edge pad area 710. The edge pad areas 710 are symmetrically disposed with respect to the center of the semiconductor substrate 100.

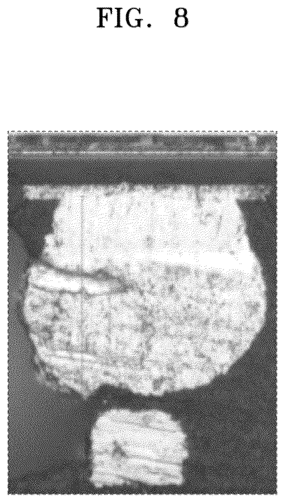

FIG. 8 illustrates a junction area between an edge area of a semiconductor chip and a substrate according to a comparative example. As shown in FIG. 8, a non-wet phenomenon occurs and a joint defect occurs because a stable bonding between a connection bump and a pad of the semiconductor chip is not formed due to a warpage phenomenon of the semiconductor substrate of the semiconductor chip. FIG. 8 shows that stable bonding between the semiconductor chip and another substrate does not occur because a crack is generated in a connection bump due to the warpage phenomenon.

According to embodiments of the inventive concept, a semiconductor package can be manufactured using a plurality of semiconductor chips 10.

The semiconductor package includes a first semiconductor chip that includes a semiconductor substrate, a center pad disposed in a central portion of the upper surface of the semiconductor substrate, and an edge pad disposed in an outer portion of the upper surface of the semiconductor substrate and that has a shape that differs from that of the center pad, a second semiconductor chip stacked on the first semiconductor chip, a first connection bump disposed between the first semiconductor chip and the second semiconductor chip and that contacts the center pad, and a second connection bump disposed between the first semiconductor chip and the second semiconductor chip and that contacts the edge pad.

An underfill material layer may be formed between the semiconductor chip 10 and another semiconductor chip 10. The underfill material layer may be disposed between a plurality of semiconductor chips 10 to surround the side surface of the connection bump 400. The underfill material layer may include, for example, an epoxy resin.

In some embodiments, the underfill material layer is a part of a molding member formed using a molded underfill (MUF) method. The molding member surrounds some or all of the plurality of semiconductor chips 10 and is formed on a package substrate.

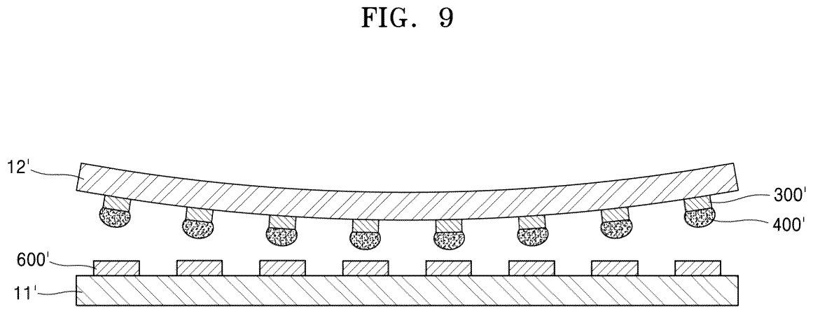

FIG. 9 illustrates a method of manufacturing a semiconductor package, according to a comparative example. In FIG. 9, the pads 600 of a lower semiconductor chip 11′ all have the same design. When the semiconductor package is manufactured, a non-wet defect occurs at a junction between the outer portion of an upper semiconductor chip 12′ and the lower semiconductor chip 11′ due to a warpage phenomenon of the upper semiconductor chip 12′.

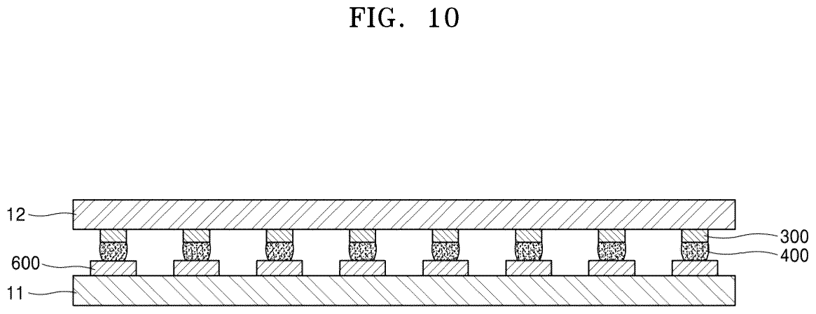

FIG. 10 illustrates a semiconductor package according to an embodiment. FIG. 10 shows a semiconductor package to which the first semiconductor chip 11 and the second semiconductor chip 12 are bonded and to which a dualized pad design according to the inventive concept is applied.

Referring to FIG. 10, in an embodiment, a semiconductor package is manufactured by electrically connecting the first semiconductor chip 11 and the second semiconductor chip 12. The second semiconductor chip 12 is the same type of semiconductor chip and includes the same individual devices as the first semiconductor chip 11. Alternatively, the second semiconductor chip 12 is a heterogeneous semiconductor chip that includes an individual device that differs from that of the first semiconductor chip 11.

According to an embodiment, the second semiconductor chip 12 contacts the center pad 610 and the edge pad 620 on which respective connection bumps 400 are formed on the upper surface of the first semiconductor chip 11, so that the upper surface of the first semiconductor chip 11 and the lower surface of the second semiconductor chip 12 are electrically connected to overlap and face each other.

The second semiconductor chip 12 overlaps the first semiconductor chip 11 in the vertical direction without a warpage phenomenon. All of the pads 600 disposed on the upper surface of the first semiconductor chip 11 respectively contact the connection bumps 400 of the second semiconductor chip 12.

The center pad 610 has a polygonal shape, and the edge pad 620 includes a polygonal center pad portion and a protruding pad portion that extends from an edge of the center pad portion in a lateral direction.

The protruding pad portions of the edge pads 620 have a square shape. The protruding pad portions of the edge pads 620 are spaced apart from each other along an edge of the center pad portion. The second connection bump 400 continuously contact side surfaces of the protruding pad portions of the edge pads 620.

A semiconductor package that includes the two semiconductor chips 11 and 12 is shown in FIG. 10, but embodiments of the inventive concept are not necessarily limited thereto. As described above, a semiconductor package can be manufactured by electrically connecting a plurality of semiconductor chips.

A semiconductor package can be manufactured by electrically connecting first to fourth semiconductor chips by using four semiconductor chips. A semiconductor package can be manufactured by electrically connecting first to eighth semiconductor chips by using eight semiconductor chips. A semiconductor package that has excellent mechanical strength and a compact size can be manufactured by reducing the warpage phenomenon.

While embodiments of the inventive concept have been particularly shown and described with reference to drawings thereof, it will be understood that various changes in form and details may be made therein without departing from the spirit and scope of the following claims.

What is claimed is:

1. A semiconductor chip, comprising:
a semiconductor substrate that includes an upper surface and a lower surface opposite to the upper surface, and a center pad disposed on the upper surface;
a wiring structure that includes a wiring insulating layer disposed on a lower surface of the semiconductor substrate and a wiring pattern disposed in the wiring insulating layer and electrically connected to the semiconductor substrate;
a first bump pad disposed on a first surface of the wiring structure and electrically connected to the wiring pattern; and
a first connection bump that connects the first bump pad to an external device.

2. The semiconductor chip of claim 1, wherein a thickness of the center pad in a vertical direction ranges from 2 μm to 3 μm.

3. The semiconductor chip of claim 1, wherein the center pad has a regular octagon shape with a side length of 1 μm.

4. The semiconductor chip of claim 1, wherein a material of the center pad includes nickel.

5. The semiconductor chip of claim 1, further comprising:
an edge pad disposed on the upper surface of the semiconductor substrate;
a second bump pad disposed on the first surface of the wiring structure and electrically connected to the wiring pattern; and
a second connection bump that connects the second bump pad to an external device.

6. The semiconductor chip of claim 5, wherein a thickness of the edge pad in a vertical direction is same as a thickness of the center pad in the vertical direction and ranges from 2 μm to 3 μm.

7. The semiconductor chip of claim 5, wherein the edge pad has an extended octagon shape formed by extending squares, each having a side length of 1 μm, from four non-continuous sides of a regular octagon that has a side length of 1 μm.

8. The semiconductor chip of claim 5, wherein a material of the edge pad includes nickel.

9. The semiconductor chip of claim 5, wherein the second bump pad is spaced apart from the first bump pad.

10. The semiconductor chip of claim 5, wherein a material of the first bump pad and a material of the second bump pad include at least one of copper or nickel.

11. The semiconductor chip of claim 5, wherein the first connection bump and the second connection bump include solder.

12. The semiconductor chip of claim 5, wherein:
defining an end of one side surface of the semiconductor substrate as a point S₁, an end of another side surface of the semiconductor substrate i as a point S₄, dividing a distance between the point S₁ and the point S₄, defining a point close to the point S₁ as a point S₂, a point distant from the point S₁ as a point S₃, and a central point between the one side surface and the another side surface as a point C,
the center pad is disposed in an area between the points S₂ and S₃, and
the edge pad is disposed in an area between the points S₁ and S₂ and in an area between the points S₃ and S₄.

13. The semiconductor chip of claim 12, wherein when a thickness of the semiconductor substrate is reduced,
the point S₂ shifts to a point S₂₂ between the points S₂ and C,
the point S₃ shifts to a point S₃₃ between the points S₃ and C, and
the points S₂₂ and S₃₃ are spaced apart from the point C by a same distance.

14. A semiconductor package, comprising:
a first semiconductor chip that includes a semiconductor substrate;
a center pad disposed at a central portion of an upper surface of the semiconductor substrate;
an edge pad disposed on an outer portion of the upper surface of the semiconductor substrate;
a second semiconductor chip stacked on the first semiconductor chip;
a first connection bump disposed between the first semiconductor chip and the second semiconductor chip and that contacts the center pad; and
a second connection bump disposed between the first semiconductor chip and the second semiconductor chip and that contacts the edge pad,
wherein a shape of the edge pad differs from a shape of the center pad.

15. The semiconductor package of claim 14, wherein
the center pad has a polygonal shape, and
the edge pad includes a polygonal center pad portion and a protruding pad portion that extends from an edge of the center pad portion in a lateral direction.

16. The semiconductor package of claim 15, wherein each of the protruding pad portions of the edge pad has a square shape.

17. The semiconductor package of claim 15, wherein the protruding pad portions of the edge pad are spaced apart from each other along an edge of the center pad portion.

18. The semiconductor package of claim 15, wherein the second connection bump continuously contacts side surfaces of the protruding pad portions of the edge pad.

19. The semiconductor package of claim 15, wherein a thickness between an upper surface and a lower surface of each of the first semiconductor chip and the second semiconductor chip is equal to or less than 37 μm.

20. The semiconductor package of claim 15, wherein the second semiconductor chip overlaps the first semiconductor chip in a vertical direction without a warpage phenomenon.
